(19) United States
(12) Patent Application Publication
(10) Pub. No.: US 2025/0277859 A1
(43) Pub. Date: Sep. 4, 2025

(54) ABNORMAL CELL DIAGNOSIS DEVICE AND METHOD USING CELL VOLTAGE DEVIATION

(71) Applicant: Samsung SDI Co., Ltd., Yongin-si (KR)

(72) Inventors: Dae Sung Lee, Suwon-si (KR); Jin Seon Baek, Suwon-si (KR); Hyun Soo Kim, Suwon-si (KR); Hyun Chul Do, Suwon-si (KR)

(73) Assignee: Samsung SDI Co., Ltd., Yongin-si (KR)

(21) Appl. No.: 18/781,755

(22) Filed: Jul. 23, 2024

(30) Foreign Application Priority Data
Mar. 4, 2024 (KR) 10-2024-0030745

(51) Int. Cl. G01R 31/3835; H01M 10/42; H01M 10/48

(52) U.S. Cl. CPC G01R 31/3835; H01M 10/425; H01M 10/482; H01M 2010/4271

(57) ABSTRACT

Disclosed herein is an abnormal battery cell diagnosis device and method for identifying an abnormal battery cell. The abnormal battery cell diagnosis device includes a voltage measurement module configured to measure an initial open circuit voltage (OCV) or closed circuit voltage (CCV) of each battery cell, a timer configured to determine a minimum rest time for a battery cell of a battery pack, and a processor configured to calculate an inter quartile range (IQR) based on the initial OCV or CCV depending on whether the minimum rest time is satisfied, to set an outlier criterion, and to detect an abnormal battery cell using the set outlier criterion.

### CROSS-REFERENCE TO RELATED APPLICATIONS

This application claims priority to and the benefit under 35 U.S.C. § 119(a)-(d) of Korean Patent Application No. 10-2024-0030745, filed at the Korean Intellectual Property Office on Mar. 4, 2024, the entire contents of which are incorporated herein by reference.

### FIELD

Aspects of embodiments of the present disclosure relates to a device and a method that can diagnose an abnormal battery cell using a battery cell voltage deviation.

### BACKGROUND

A battery management system (BMS) is a device capable of determining whether a battery is in a charging or discharging state. A BMS may also be arranged to continuously measure a battery temperature and/or a battery voltage to detect and mitigate a failure of the battery. A purpose of the BMS function is to detect the occurrence of an abnormality of one or more battery cells quickly and in advance of a battery failure, thereby preventing a dangerous situation involving the battery.

The above information disclosed in this Background section is for enhancement of understanding of the background of the present disclosure, and therefore, it may contain information that does not constitute related (or prior) art.

### SUMMARY

The present disclosure provides an abnormal battery cell diagnosis device and a method of using a battery cell voltage deviation to detect an abnormal battery cell. The method includes using a technique of identifying outlier battery cells by comparing measurements acquired from a battery cell to a median of battery cell data acquired at a specific time point and operational situation. The method uses a voltage difference between battery cells to identify abnormal battery cells, and increases an efficiency of detecting abnormal battery.

According to an aspect of the present disclosure, an abnormal battery cell diagnosis device is provided. The abnormal battery cell diagnosis device uses battery cell voltage deviation to identify abnormal battery cells, and the abnormal battery cell diagnosis device includes a voltage measurement module configured to measure an initial open circuit voltage (OCV) or closed circuit voltage (CCV) of each battery cell, a timer configured to count a minimum rest time for each battery cell, and a processor configured to calculate an inter quartile range (IQR) based on the initial OCV or CCV depending on whether the minimum rest time is satisfied. The processor is further configured to set an outlier criterion and to detect an abnormal battery cell on the basis of the set outlier criterion.

The foregoing is a non-limiting summary of the disclosure, and it should be appreciated that various alterations, modifications, and improvements will readily occur to those skilled in the art and are within the spirit and scope of the technology described herein.

### BRIEF DESCRIPTION OF DRAWINGS

The following drawings attached to this specification illustrate embodiments of the present disclosure, and further describe aspects and features of the present disclosure together with the detailed description of the present disclosure. Thus, the present disclosure should not be construed as being limited to the drawings:

FIG. 1 is a diagram illustrating an example of a battery module, according to one embodiment of the technology described herein;

FIG. 2 is a block diagram of an abnormal battery cell diagnosis device, according to one embodiment of the technology described herein;

FIGS. 3 to 5 are exemplary diagrams for describing a method of setting an outlier criterion, according to one embodiment of the technology described herein;

FIG. 6 is a flowchart for describing an abnormal battery cell diagnosis method using a battery cell voltage deviation, according to one embodiment of the technology described herein; and

FIG. 7 is a flowchart for describing an abnormal battery cell diagnosis method using a battery cell voltage deviation, according to another embodiment of the technology described herein.

### DETAILED DESCRIPTION

Hereinafter, embodiments of the present disclosure will be described, in detail, with reference to the accompanying drawings. The terms or words used in this specification and claims should not be construed as being limited to the usual or dictionary meaning and should be interpreted as meaning and concept consistent with the technical idea of the present disclosure based on the principle that the inventor can be his/her own lexicographer.

The embodiments described in this specification and the configurations shown in the drawings are only some of the embodiments of the present disclosure and do not represent all of the technical ideas, aspects, and features of the present disclosure. Accordingly, it should be understood that there may be various equivalents and modifications that can replace or modify the embodiments described herein at the time of filing this application.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. Throughout the specification, when “A and/or B” is stated, it means A, B or A and B, unless otherwise stated. That is, “and/or” includes any or all combinations of a plurality of items enumerated. When “C to D” is stated, it means C or more and D or less, unless otherwise specified. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. When phrases such as “at least one of A, B and C, “at least one of A, B or C,” “at least one selected from a group of A, B and C,” or “at least one selected from among A, B and C” are used to designate a list of elements A, B and C, the phrase may refer to any and all suitable combinations or a subset of A, B and C, such as A, B, C, A and B, A and C, B and C, or A and B and C. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

References to two compared elements, features, etc. as being “the same” may mean that they are “substantially the same.” Thus, the phrase “substantially the same” may include a case having a deviation that is considered low in the art, for example, a deviation of 5% or less. In addition, when a certain parameter is referred to as being uniform in a given region, it may mean that it is uniform in terms of an average.

Throughout the specification, unless otherwise stated, each element may be singular or plural.

When an arbitrary element is referred to as being disposed (or located or positioned) on the “above (or below)” or “on (or under)” a component, it may mean that the arbitrary element is placed in contact with the upper (or lower) surface of the component and may also mean that another component may be interposed between the component and any arbitrary element disposed (or located or positioned) on (or under) the component.

In addition, it will be understood that when an element is referred to as being “coupled,” “linked” or “connected” to another element, the elements may be directly “coupled,” “linked” or “connected” to each other, or an intervening element may be present therebetween, through which the element may be “coupled,” “linked” or “connected” to another element. In addition, when a part is referred to as being “electrically coupled” to another part, the part can be directly connected to another part or an intervening part may be present therebetween such that the part and another part are indirectly connected to each other.

When the exact cause of a battery cell abnormality cannot be identified because causes of the abnormality may be diverse, abnormal battery cells may be detected by setting a threshold value based on “worst case” parameters. However, such a threshold value may lead to an increased probability of identifying normal battery cells as abnormal. In an abnormal battery cell, there may be a high probability of an abnormality arising during operation of the battery cell, but such abnormalities typically cannot be clearly or easily defined by specific battery cell parameters. Measurements of battery cell parameters have shown that there are wide ranges of battery cell parameter values exhibited by “normal” battery cells such that certain values cannot be specified as absolute criteria for identifying abnormal battery cell conditions that may lead to battery cell failure.

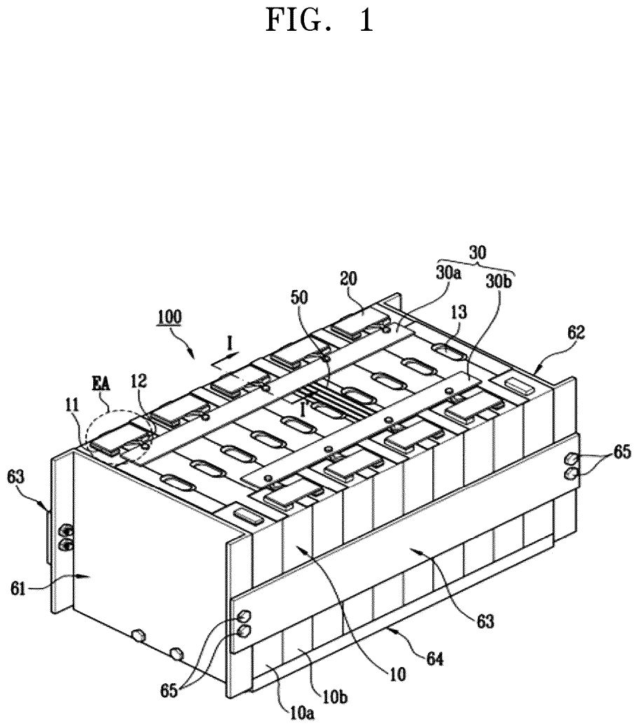

FIG. 1 is a diagram illustrating an example of a battery module according to one embodiment of the technology described herein.

Referring to FIG. 1, a battery module 100 according to the technology described herein includes a plurality of battery cells 10 provided with terminals 11 and 12 and arranged in one direction, a connection tab 20 which connects a battery cell 10a to an adjacent battery cell 10b, and a protection circuit module 30 with one end connected to the connection tab 20. The protection circuit module 30 may be a battery management system (BMS). In addition, the connection tab 20 includes a body which contacts the terminals 11 and 12 between the adjacent battery cells 10a and 10b, and an extension extending from the body to connect to the protection circuit module 30. The connection tab 20 may be a bus bar.

First, the battery cell 10 may be formed of a battery case, an electrode assembly, and an electrolyte which are disposed in the battery case. The electrode assembly and the electrolyte react electrochemically to generate energy. The terminals 11 and 12 electrically connected to the connection tab 20 and a vent 13 that is a discharge passage for a gas generated inside the battery cell 10 may be provided on one side of the battery cell 10. The terminals 11 and 12 of the battery cell 10 may be a positive electrode terminal 11 and a negative electrode terminal 12 having different polarities, and the terminals 11 and 12 of the adjacent battery cells 10a and 10b may be electrically connected in series or in parallel by the connection tab 20. It should be appreciated that, although an example of the serial connection has been described, the technology described herein is not limited to this structure, and of course, various connection structures can alternatively be employed. In addition, the number and arrangement of the battery cells 10 are not limited to the structure shown in FIG. 1 and may include a greater number or a smaller number of battery cells than are depicted in the example of FIG. 1.

The plurality of battery cells 10 may be disposed in one direction so that wide surfaces of the battery cells 10 face each other, and the plurality of disposed battery cells 10 may be fixed by housings. The housings may include a pair of end plates 61 and 62 facing the wide surfaces of the battery cells 10, and a side plate 63 and a bottom plate 64 which connect the pair of end plates 61 and 62. The side plate 63 may support a side surface of the battery cell 10, and the bottom plate 64 may support a bottom surface of the battery cell 10. In addition, the pair of end plates 61 and 62, the side plate 63, and the bottom plate 64 may be connected by members such as bolts 65.

Electronic components and protection circuits may be mounted on the protection circuit module 30, and the protection circuit module 30 may be electrically connected to the connection tab 20. The protection circuit module 30 may include a first protection circuit module 30a and a second protection circuit module 30b, which extend from different positions in a direction in which the plurality of battery cells 10 are disposed. In this case, the first protection circuit module 30a and the second protection circuit module 30b may be spaced apart at a predetermined distance and positioned parallel to each other so that each of the first protection circuit module 30a and the second protection circuit module 30b may be electrically connected to an adjacent connection tab 20. For example, the first protection circuit module 30a is formed to extend on one upper side of the plurality of battery cells 10 in the direction in which the plurality of battery cells 10 are disposed, and the second protection circuit module 30b extends on the other upper side of the plurality of battery cells 10 in the direction in which the plurality of battery cells 10 are disposed. The second protection circuit module 30b may be positioned to be spaced a predetermined distance from the first protection circuit module 30a with the first protection circuit module 30a and the vent 13 interposed therebetween and disposed parallel to the first protection circuit module 30a.

In this way, the two protection circuit modules are separately disposed parallel to each other in the direction in which the plurality of battery cells are disposed so that an area of a printed circuit board (PCB) constituting the protection circuit module is minimized. The protection circuit module is formed of the two protection circuit modules so that an unnecessary PCB area is minimized. In addition, the first protection circuit module 30a and the second protection circuit module 30b may be connected to each other by a conductive connection member 50. In this case, one side of the connection member 50 is connected to the first protection circuit module 30a, and the other side thereof is connected to the second protection circuit module 30b so that an electrical connection can be made between the two protection circuit modules. The connection may be performed by any one of soldering, resistance welding, laser welding, and projection welding.

In addition, the connection member 50 may be, for example, an electric wire. In addition, the connection member 50 may be made of an elastic or flexible material. It is possible to check and manage whether a voltage, a temperature, and a current of the plurality of battery cells 10 are normal through the connection member 50. That is, information such as a voltage, a current, and a temperature received by the first protection circuit module from adjacent connection tabs and information such as a voltage, a current, and a temperature received by the second protection circuit module from adjacent connection tabs may be integrated and managed by the protection circuit module through the connection member.

In addition, when the battery cell 10 swells, an impact is absorbed by elasticity or flexibility of the connection member 50 so that the first and second protection circuit modules 30a and 30b are prevented from being damaged.

In addition, it should be appreciated that a shape and a structure of the connection member 50 are not limited to those shown in FIG. 1, as aspects of the technology described herein are not limited in this respect.

In this way, since the protection circuit module 30 is provided as the first and second protection circuit modules 30a and 30b, the area of the PCB constituting the protection circuit module may be minimized so that a space inside the battery module can be secured. This improves work efficiency by not only connecting the connection tab 20 to the protection circuit module 30, but also making repairs easier when an abnormality is detected in the battery module.

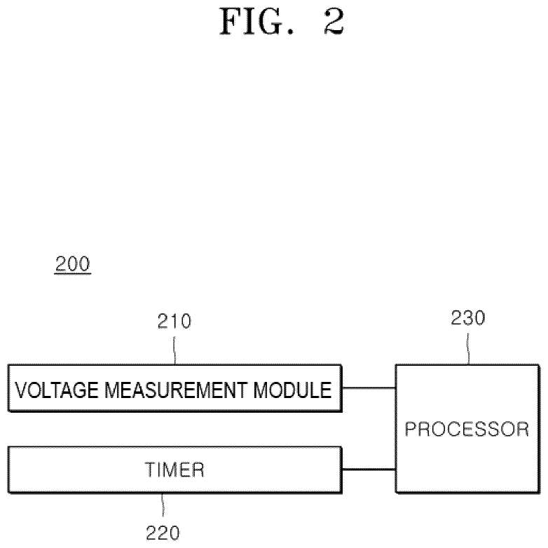

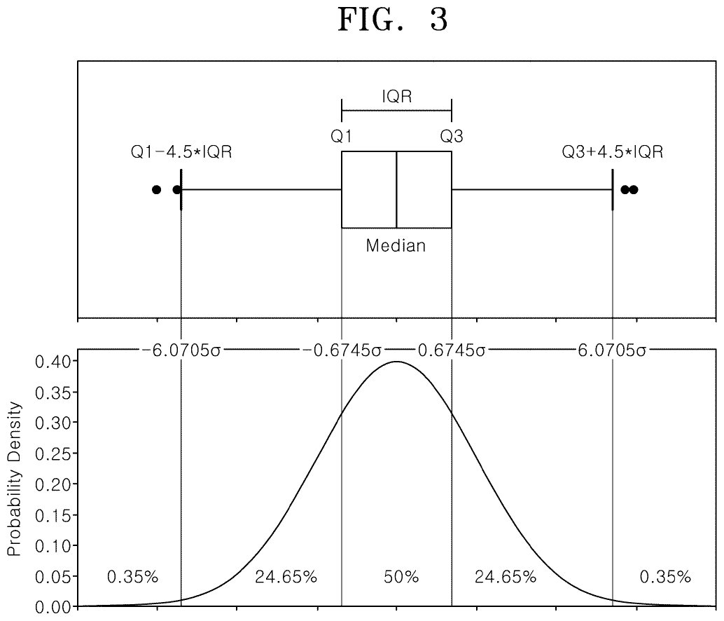

FIG. 2 is a block diagram for describing an abnormal battery cell diagnosis device using a battery cell voltage deviation according to one embodiment of the technology described herein, and FIGS. 3 to 5 are exemplary diagrams for describing a method of setting an outlier criterion according to one embodiment of the technology described herein.

Referring to FIG. 2, an abnormal battery cell diagnosis device 200 for diagnosing battery cells using battery cell voltage deviation is shown according to one embodiment of the technology described herein. The abnormal battery cell diagnosis device 200 may include a voltage measurement module 210, a timer 220, and a processor 230, in some embodiments.

In some embodiments, the voltage measurement module 210 may be configured to measure an initial open circuit voltage (OCV) or closed circuit voltage (CCV) for each battery cell of a battery pack. To this end, the voltage measurement module 210 may include a voltage sensor.

In some embodiments, the timer 220 may determine a minimum rest time for each battery cell of the battery pack. Here, the minimum rest time may be preset to, for example, two hours.

In some embodiments, the processor 230 may be configured to detect an outlier of a voltage distribution of an individual battery cell using a calculated inter quartile range (IQR). The processor 230 may be configured to distinguish an idle situation (e.g., a battery idle mode) from a charging situation (e.g., a battery charging mode) and to add an activation condition and/or an identification condition to complement an IQR method.

In some embodiments, the processor 230 may be configured to calculate an IQR based on the initial OCV or CCV depending on whether the minimum rest time is satisfied (e.g., whether the minimum rest time is greater than a predetermined value). The processor 230 may further be configured to set an outlier criterion for detecting an abnormal battery cell. Hereinafter, a process of setting an outlier criterion according to the battery idle mode and the battery charging mode is described with reference to FIGS. 3 to 5.

In some embodiments, in the battery idle mode, the processor 230 may be configured to detect an outlier (e.g., an outlier battery cell voltage) in a situation in which the minimum rest time is satisfied to obtain a stable voltage. In this case, a sensing circuit may be used to measure a voltage and a temperature of each battery cell before a high voltage is connected. The processor 230 may calculate a median voltage value, an IQR, and an outlier criterion of the voltage of an entire battery pack on the basis of the measured voltage from battery cells within the battery pack.

In some embodiments, when the minimum rest time is satisfied, the processor 230 may be configured to calculate an IQR based on the initial OCV and set an outlier criterion for detecting an abnormal battery cell in the battery idle mode.

In some embodiments, when a time counted by the timer 220 exceeds the minimum rest time (e.g., two hours), as shown in FIG. 3, the processor 230 may obtain a median of the voltage of the entire battery pack based on the initial OCV and calculate the IQR based on the initial OCV on the basis of a first quartile Q1 value and a third quartile Q3 value. The processor 230 may set the outlier criterion for detecting an abnormal battery cell in a battery idle state using the calculated IQR.

In some embodiments, the outlier criterion for detecting an abnormal battery cell in the battery idle state may be set to a calculated result value of the following Equation 1:

$$outlier criterion = Q 1 - 4.5 * IQR \qquad [ Equation 1 ]$$

In such embodiments, when the IQR (e.g., 10 mV) is greater than or equal to a set voltage (e.g., 8 mV), the outlier criterion may be set to a result value calculated by applying 10 mV to the IQR of Equation 1. When the IQR (e.g., 6 mV) is less than the set voltage (e.g., 8 mV), the outlier criterion may be set to a result value calculated by applying 6 mV to the IQR of Equation 1.

In some embodiments, the processor 230 may be configured to detect an abnormal battery cell in the battery idle state on the basis of the set outlier criterion. That is, the processor 230 may compare the voltage of each battery cell with the outlier criterion and identify a battery cell whose voltage is greater than the outlier criterion as an abnormal battery cell.

As described above, in some embodiments, the processor 230 may be configured to set the outlier criteria for the entire section to Q1−4.5*IQR and Q3+4.5*IQR and to use “Q1−4.5*IQR” corresponding to Median-Min for detecting Min. Cell which has a high reduction rate when the battery is idle alone.

In some embodiments, the processor 230 may be configured to set the value of the IQR to be equal to 8 mV when the calculated value of the IQR is less than 8 mV for a section in which a difference between the battery cells is small. The processor 230 may further be configured to calculate the Median-Min values such that an abnormality is not detected when the battery cell voltage is within 40 mV. The processor 230 may be configured to restrict a high voltage connection and prohibit use of the battery in a situation in which the abnormal battery cell is identified.

In some embodiments, when the minimum rest time is not satisfied (e.g., when the determined minimum rest time is less than or equal to the predetermined minimum rest time value), the processor 230 may be configured to calculate an IQR based on the CCV and to set an outlier criterion for detecting an abnormal battery cell when the battery cell is in the battery charging mode.

Specifically, in some embodiments, when a minimum rest time determined by the timer 220 does not exceed the predetermined minimum rest time (e.g., two hours), as shown in FIG. 3, the processor 230 may obtain a median value of the voltage of the battery cells of the entire battery pack based on the CCV and calculate the IQR based on the CCV on the basis of the first quartile Q1 value and the third quartile Q3 value.

In such embodiments, the processor 230 may be configured to calculate the IQR based on the CCV only when a battery charge amount (SOC) is greater than or equal to a set charge amount. The processor 230 may be configured to set the outlier criterion for detecting an abnormal battery cell in the battery charging mode using the calculated IQR.

In some embodiments, and like the outlier criterion for detecting an abnormal battery cell in the battery idle state, the outlier criterion for detecting an abnormal battery cell in the battery charging mode may be set to a calculated result value of Equation 1. In this case, when the IQR is smaller than a set voltage (e.g., 8 mV), the outlier criterion may be set to a result value calculated by applying the set voltage to the IQR of Equation 1.

In some embodiments, the processor 230 may be configured to detect an abnormal battery cell in the battery charging mode on the basis of the set outlier criterion. That is, the processor 230 may compare the voltage of each battery cell with the outlier criterion and detect a battery cell whose voltage is greater than the outlier criterion as an abnormal battery cell.

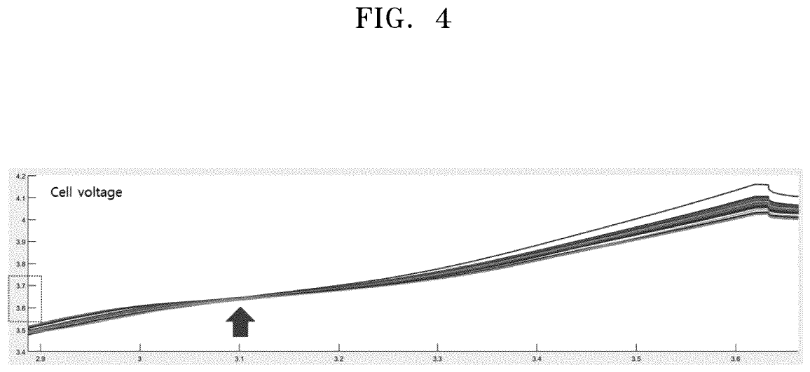

In some embodiments, in the battery charging mode, the processor 230 may be configured to restrict an SOC section condition and to detect an abnormal battery cell only in a region of SOC that is 50% or higher and in a charging mode (e.g., the battery being plugged in and charging). In this case, as shown in FIG. 4, in a section (e.g., the 3.6 V to 3.75 V section) in which no deviation between the battery cells occurs depending on the SOC section, a battery cell voltage outlier could be detected even if there is only a small voltage deviation. In this SOC section, the incorrect identification of a normal battery cell can be prevented on the basis of a minimum condition for deviation.

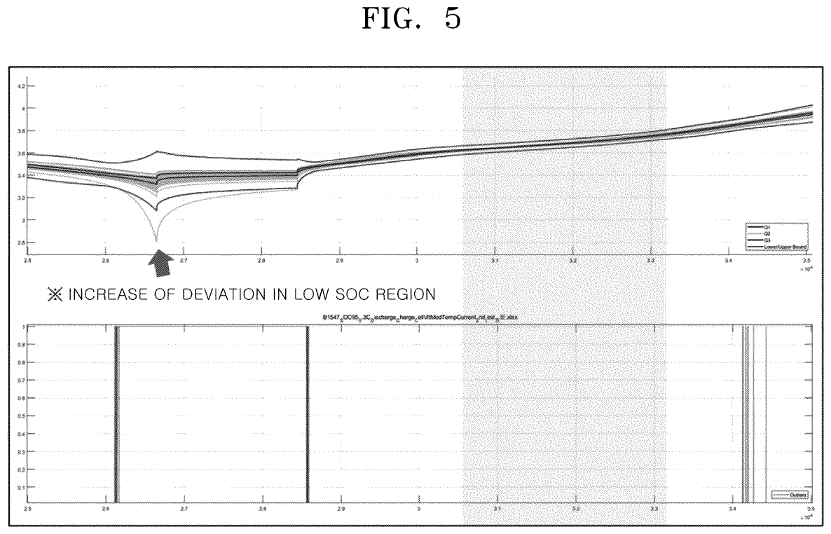

On the other hand, as shown in FIG. 5, it can be seen that, in a region in which the SOC is low, differences between the battery cells' behavior tends to become worse during discharging. Although an outlier battery cell is clear in a section in which the difference between the battery cells becomes worse, when a voltage difference between the battery cells is small, such as a specific charging section (e.g., the 3.6 V to 3.75 V section) in FIG. 4, the probability of false detection of normal battery cells may increase even with a small change. Therefore, it can be confirmed that, in order to mitigate the probability of false detection, a condition for voltage deviation is needed rather than relying on unconditional statistics.

That is, the region with a low SOC as shown in FIG. 5 may be excluded from abnormal battery cell diagnosis. On the other hand, since an SOC of 50% or more changes uniformly during charging, an inter-cell deviation in this section may be used to detect abnormal battery cells with a lower probability of false identification of normal battery cells as being abnormal.

In some embodiments, the processor 230 may include any one of a BMS, a battery pack control module (BPCM), a central processing control unit (CPU), an electronic control unit (ECU), and a micro controller unit (MCU).

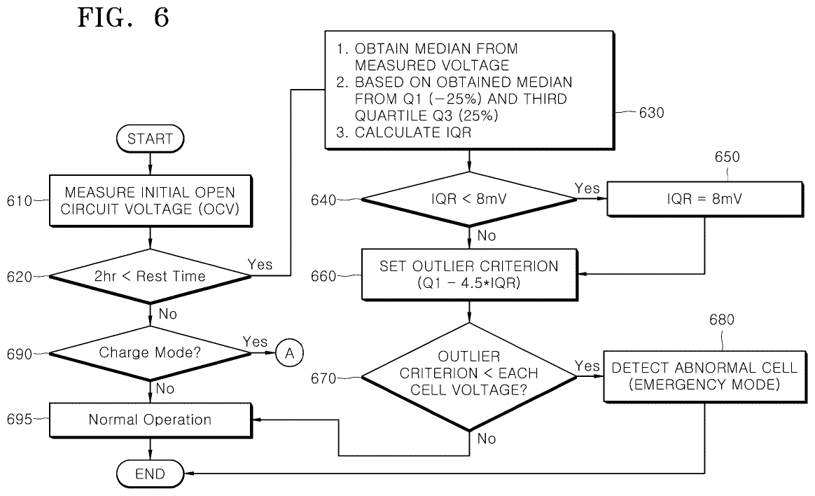

FIG. 6 is a flowchart for describing an abnormal battery cell diagnosis method using a battery cell voltage deviation according to one embodiment of the technology described herein. In particular, FIG. 6 shows a flowchart for describing an abnormal battery cell diagnosis method when the battery is in a battery idle mode.

The abnormal battery cell diagnosis method described herein is merely one example of an implementation of the technology described herein. In addition, the technology described herein is not limited to each operation and sequence described below, and various operations may be added as necessary as follows, and operations below may also be performed in different orders. This can also be applied to other examples below.

Referring to FIGS. 2 and 6, in operation 610, the voltage measurement module 210 may measure an initial OCV of each battery cell, in some embodiments.

Next, in operation 620, the processor 230 may determine whether a time measured by the timer 220 for each battery cell satisfies a minimum rest time.

In some embodiments, when the minimum rest time is satisfied (e.g., 2 hr<rest time) (“Yes” in 620), in operation 630, the processor 230 may obtain a median value of the voltage of the entire battery pack using the initial OCV. The processor 230 may calculate an IQR on the basis of a first quartile Q1 (−25%) value and a third quartile Q3 (25%) value based on the obtained median value.

In some embodiments, when the calculated IQR is smaller than a set voltage (e.g., 8 mV) (“Yes” in 640), the processor 230 may set the IQR to 8 mV in operation 650.

Next, in operation 660, the processor 230 may set an outlier criterion using the IQR (e.g., based on the following expression: outlier criterion=Q1−4.5*IQR).

Next, in operation 670, the processor 230 may compare an individual battery cell voltage with the outlier criterion.

In some embodiments, when the outlier criterion is smaller than the individual battery cell voltage (“Yes” in 670), the processor 230 may detect a corresponding battery cell as an abnormal battery cell in operation 680. On the other hand, when the outlier criterion is not smaller than the individual battery cell voltage (“No” in 670), the processor 230 may determine that the corresponding battery cell is operating normally.

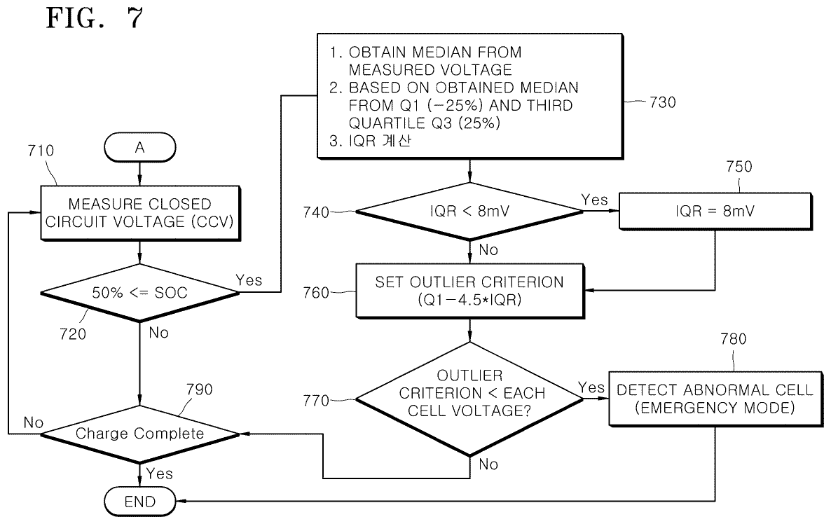

In some embodiments, when the minimum rest time is not satisfied (“No” in 620), the processor 230 may check, in operation 690, whether a current mode of operation of the battery cells is a charging mode. When the current mode is identified to be the charging mode (“Yes” in 690), the processor 230 may perform process A of FIG. 7. On the other hand, when the current mode is identified as not being the charging mode (“No” in 690), the processor 230 may determine, in operation 695, that the corresponding battery cell is operating normally.

FIG. 7 is a flowchart for describing an abnormal battery cell diagnosis method using a battery cell voltage deviation according to another embodiment of the technology described herein. In particular, FIG. 7 shows a flowchart for describing the abnormal battery cell diagnosis method (process A of FIG. 6) in the battery charging mode.

Referring to FIGS. 2 and 7, in operation 710, the voltage measurement module 210 may measure a CCV of each battery cell in some embodiments.

Next, in operation 720, the processor 230 may check whether a battery charge amount (SOC) for each battery cell is greater than or equal to a set charge amount (e.g., 50%).

In some embodiments, when the SOC is greater than or equal to 50% (“Yes” in 720), in operation 730, the processor 230 may obtain a median value of the voltages of the battery cells in the entire battery pack on the basis of the measured CCV values. The processor 230 may calculate an IQR on the basis of a first quartile Q1 (−25%) value and a third quartile Q3 (25%) value based on the obtained median value.

In some embodiments, when the calculated IQR is smaller than a set voltage (e.g., 8 mV) (“Yes” in 740), the processor 230 may set the IQR to 8 mV in operation 750.

Next, in operation 760, the processor 230 may set an outlier criterion using the IQR (Q1−4.5*IQR).

Next, in operation 770, the processor 230 may compare an individual battery cell voltage with the outlier criterion.

In some embodiments, when the outlier criterion is smaller than the individual battery cell voltage (“Yes” in 770), the processor 230 may identify a corresponding battery cell as an abnormal battery cell in operation 780. On the other hand, when the outlier criterion is not smaller than the individual battery cell voltage (“No” in 770), the processor 230, in operation 790, may determine whether charging of the battery cell is completed.

In some embodiments, operation 790 may be performed even when the SOC is not greater than or equal to 50% (“No” in 720). When the charging is determined to be completed (“Yes” in 790), the process of FIG. 7 may be terminated, but when the charging is not completed (“No” in 790), the processor 230 may return to operations 710 and perform the process of FIG. 7 again.

In accordance with the technology described herein, a method of finding outlier battery cells is provided. Voltages measured for battery cells may be compared to a median voltage value calculated using measured voltages for each battery cell of a battery pack. A voltage difference between battery cells is then used so the detection of abnormal battery cell may be more efficient and less likely to identify normal battery cells as abnormal. Additionally, the efficiency of abnormal battery cell detection can be further increased according to a characteristic of a charging state of the battery cell.

In accordance with the technology described herein, a method of finding an outlier compared to a median of battery cell data known as an interquartile range (IQR) is additionally used to classify the outlier for a characteristic of a value acquired at the same time point so that false identification of normal battery cells as abnormal can be mitigated.

However, effects that can be achieved through the technology described herein are not limited to the above-described effects and other effects that are not described may be clearly understood by those skilled in the art from the detailed descriptions.

Although the technology described herein has been described above with reference to limited embodiments and drawings, the technology described herein is not limited thereto, and various modifications and variations are possible within the scope of the technical spirit of the technology described herein and the appended claims to be described below by those skilled in the art to which the technology described herein pertains.

What is claimed is:

1. An abnormal battery cell diagnosis device comprising:
a voltage measurement module configured to measure an initial open circuit voltage (OCV) or a closed circuit voltage (CCV) of a battery cell;
a timer configured to determine a minimum rest time for the battery cell; and
a processor configured to:
calculate an interquartile range (IQR) using the measured initial OCV or the measured initial CCV, depending on whether the minimum rest time is satisfied,
set an outlier criterion based on the calculated IQR, and
identify the battery cell as a normal or an abnormal battery cell using, at least in part, the set outlier criterion.

2. The abnormal battery cell diagnosis device of claim 1, wherein, if the determined minimum rest time is greater than a minimum rest time threshold value, the processor is configured to calculate the IQR based on the measured initial OCV and to set the outlier criterion for the battery cell when it is in a battery idle mode.

3. The abnormal battery cell diagnosis device of claim 2, wherein the processor is configured to:
obtain a median value of a voltage of an entire battery pack including the battery cell based on an initial OCV measured for each battery cell of the entire battery pack, and
to calculate the IQR using a first quartile (Q1) value and a third quartile (Q3) value, each determined using the obtained median value.

4. The abnormal battery cell diagnosis device of claim 3, wherein the outlier criterion is determined according to the following equation:
$$outlier criterion = Q 1 - 4.5 * IQR .$$

5. The abnormal battery cell diagnosis device of claim 4, wherein, when the IQR is smaller than a set voltage, the outlier criterion is determined according to the following equation:
$$outlier criterion = Q 1 - 4.5 * ( set voltage ) .$$

6. The abnormal battery cell diagnosis device of claim 1, wherein, if the determined minimum rest time is less than a minimum rest time threshold value, the processor is configured to calculate the IQR based on the measured initial CCV and to set the outlier criterion for the battery cell when it is in a battery charging mode.

7. The abnormal battery cell diagnosis device of claim 6, wherein the processor is configured to:
obtain a median value of a voltage of an entire battery pack based on an initial CCV measured for each battery cell of the entire battery pack, and
to calculate the IQR using a first quartile (Q1) value and a third quartile (Q3) value, each determined using the obtained median value.

8. The abnormal battery cell diagnosis device of claim 7, wherein the processor is configured to calculate the IQR only when a battery charge amount (SOC) is greater than or equal to a set charge amount.

9. The abnormal battery cell diagnosis device of claim 7, wherein the outlier criterion is determined according to the following equation:
$$outlier criterion = Q 1 - 4.5 * IQR .$$

10. The abnormal battery cell diagnosis device of claim 9, wherein, when the IQR is smaller than a set voltage, the outlier criterion is determined according to the following equation:
$$outlier criterion = Q 1 - 4.5 * ( set voltage ) .$$

11. An abnormal battery cell diagnosis method comprising:
measuring, using a voltage measurement module, an initial open circuit voltage (OCV) or closed circuit voltage (CCV) for a battery cell;
determining, by a processor and a timer, a minimum rest time for the battery cell;
calculating, by the processor, an interquartile range (IQR) using the measured initial OCV or the measured initial CCV, depending on whether the minimum rest time is satisfied and setting an outlier criterion;
setting, using the processor, an outlier criterion based on the calculated IQR; and
identifying, by the processor, the battery cell as a normal or an abnormal battery cell using, at least in part, the set outlier criterion.

12. The abnormal battery cell diagnosis method of claim 11, wherein setting the outlier criterion comprises:
if the determined minimum rest time is greater than a minimum rest time threshold value, calculating the IQR based on the measured initial OCV; and
setting the outlier criterion for the battery cell in a battery idle state.

13. The abnormal battery cell diagnosis method of claim 12, wherein calculating the IQR based on the measured initial OCV comprises:
obtaining a median value of a voltage of an entire battery pack including the battery cell based on an OCV measured for each battery cell of the entire battery pack; and
calculating the IQR using a first quartile (Q1) value and a third quartile (Q3) value, each determined using the obtained median value.

14. The abnormal battery cell diagnosis method of claim 13, wherein setting the outlier criterion comprises determining the outlier criterion according to the following equation:
$$outlier criterion = Q 1 - 4.5 * IQR .$$

15. The abnormal battery cell diagnosis method of claim 14, wherein, when the IQR is smaller than a set voltage, setting the outlier criterion comprises determining the outlier criterion according to the following equation:
$$outlier criterion = Q 1 - 4.5 * ( set voltage ) .$$

16. The abnormal battery cell diagnosis method of claim 11, wherein setting the outlier criterion comprises:
if the determined minimum rest time is less than a minimum rest time threshold value, calculating the IQR based on the measured initial CCV; and
setting the outlier criterion for the battery cell in a battery charging mode.

17. The abnormal battery cell diagnosis method of claim 16, wherein calculating the IQR based on the measured initial CCV includes:
obtaining a median value of a voltage of an entire battery pack including the battery cell based on a CCV measured for each battery cell of the entire battery pack; and
calculating the IQR using a first quartile (Q1) value and a third quartile (Q3) value, each determined using the obtained median value.

18. The abnormal battery cell diagnosis method of claim 17, wherein calculating the IQR based on the CCV is performed only when a battery charge amount (SOC) is greater than or equal to a set charge amount.

19. The abnormal battery cell diagnosis method of claim 17, wherein setting the outlier criterion comprises determining the outlier criterion according to the following equation:
$$outlier criterion = Q 1 - 4.5 * IQR .$$

20. The abnormal battery cell diagnosis method of claim 19, wherein, when the IQR is smaller than a set voltage, setting the outlier criterion comprises determining the outlier criterion according to the following equation:
$$outlier criterion = Q 1 - 4.5 * ( set voltage ) .$$
